(19) United States
(12) Patent Application Publication
(10) Pub. No.: US 2007/0187828 A1
(43) Pub. Date: Aug. 16, 2007

(54) ILD LAYER WITH INTERMEDIATE DIELECTRIC CONSTANT MATERIAL IMMEDIATELY BELOW SILICON DIOXIDE BASED ILD LAYER

(75) Inventors: Mukta G. Farooq, Hopewell Junction, NY (US); Robert Hannon, Wappingers Falls, NY (US); Ian D. Melville, Highland, NY (US); Donna S. Zupanski-Nielsen, Yorktown Heights, NY (US)

Correspondence Address: HOFFMAN, WARNICK & D'ALESSANDRO LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/307,600

(22) Filed: Feb. 14, 2006

(51) Int. Cl. H01L 23/52

(52) U.S. Cl. 257/758

(57) ABSTRACT

An integrated circuit (IC) chip and related package are disclosed including a first interlevel dielectric (ILD) layer(s) including an ultra low dielectric constant (ULK) material, a second ILD layer(s) including a silicon dioxide (SiO₂) based dielectric material above the first ILD layer(s), and a transitional ILD layer including an intermediate dielectric constant material. The transitional ILD layer is positioned directly below a lowermost one of the second ILD layer(s), excepting any isolation layer, which represents the layer most susceptible to failure. The intermediate dielectric constant material can have a dielectric constant and an elastic modulus greater than that of the ULK material and less than that of the SiO₂ based dielectric material. Hence, the intermediate dielectric constant provides adequate electrical properties, but also absorbs more of the stress than the typical ULK material, which reduces the likelihood of failure. A method of forming the IC chip is also disclosed.

### BACKGROUND OF THE INVENTION

1. Technical Field

The invention relates generally to integrated circuit fabrication, and more particularly, to an integrated circuit chip, a related chip package and method that provide an intermediate dielectric constant material at an interlevel dielectric (ILD) layer directly below a silicon dioxide (SiO₂) based dielectric material to reduce stress in back-end-of-line layers.

2. BACKGROUND ART

As the integrated circuit industry continues to drive toward reduced feature size one of the challenges is maintaining the structural reliability relative to chip package interactions. Chip package interactions include structural interactions between multi-level interconnect structures (referred to as back-end-of-line (BEOL) layers and including all layers after a first metal (M1) layer) of a chip, interconnections between the chip and substrates. Conventional BEOL layers require more fragile low dielectric constant (low-k) dielectric materials having coefficient of thermal expansion (CTE) that differ significantly from the substrates (e.g., organic laminate) to which they are coupled.

FIG. 1 shows one example of a chip package 8 including a chip 10 having conventional BEOL layers 12, interconnections 14 (e.g., wire bonds) and a substrate 16 (shown in part). Typically, BEOL layers 12 include a number of ILD layers 20 including hybrid low dielectric constant (low-k) material (e.g., k>approximately 3) formed directly over a number of ILD layers 22 including ultra low dielectric constant (ULK) material (e.g., k<approximately 3). ILD layers 20 typically include hybrid silicon dioxide (SiO₂) based dielectric material formed using, for example, tetraethyl orthosilicate, Si(OC₂H₅)₄ (TEOS) for a metal level 20 M, and fluorinated TEOS (FTEOS) for a via level 20V. ILD layers 22 may include any ULK material such as porous hydrogenated silicon oxycarbide (SiCOH). In this example, BEOL layers 12 may have a CTE value of approximately 3 parts per million per degree Celsius (ppm/° C.) and substrate 16 (shown in part only) may have a CTE value of approximately 15-18 ppm/° C. As a result of these CTE differences, stresses are created within components of chip package 8, e.g., within substrate 16, interconnections 14 and chip 10, which can cause structural failure such as breakage, delamination, etc., as they are propagated to BEOL layers 12 of chip 10. The likelihood of failure increases as feature sizes in BEOL layers 12 continue to be minimized and the low-k dielectric material of BEOL layers 12 become increasingly fragile. Failure may occur during fabrication (as yield losses), during testing (qualification fails) and, as a worst case scenario, during operation in the field.

### SUMMARY OF THE INVENTION

An integrated circuit (IC) chip and related package are disclosed including a first interlevel dielectric (ILD) layer(s) including an ultra low dielectric constant (ULK) material, a second ILD layer(s) including a silicon dioxide (SiO₂) based dielectric material above the first ILD layer(s), and a transitional ILD layer including an intermediate dielectric constant material. The transitional ILD layer is positioned directly below a lowermost one of the second ILD layer(s), excepting any isolation layer, which represents the layer most susceptible to failure. The intermediate dielectric constant material can have a dielectric constant and an elastic modulus greater than that of the ULK material and less than that of the SiO₂ based dielectric material. Hence, the intermediate dielectric constant provides adequate electrical properties, but also absorbs more of the stress than the typical ULK material, which reduces the likelihood of failure. A method of forming the IC chip is also disclosed.

A first aspect of the invention provides a method of forming a multi-level interconnect structure of an integrated circuit chip, the method comprising the steps of: forming at least one first interlevel dielectric (ILD) layer including an ultra low dielectric constant (ULK) material; forming at least one second ILD layer including a silicon dioxide (SiO₂) based dielectric material, the at least one second ILD layer positioned above the at least one first ILD layer; and forming, immediately prior to a lowermost one of the at least one second ILD layer, excepting any isolation layer, a transitional ILD layer including an intermediate dielectric constant material.

A second aspect of the invention provides an integrated circuit chip comprising: at least one first interlevel dielectric (ILD) layer including an ultra low dielectric constant (ULK) material; at least one second ILD layer including a silicon dioxide (SiO₂) based dielectric material, the at least one second ILD layer positioned above the at least one first ILD layer; and a transitional ILD layer including an intermediate dielectric constant material, the transitional ILD layer, excepting any isolation layer, positioned directly below a lowermost one of the at least one second ILD layer.

A third aspect of the invention provides an integrated circuit chip package comprising: a substrate; an integrated circuit (IC) chip including a multi-level interconnect structure including: at least one first interlevel dielectric (ILD) layer including an ultra low dielectric constant (ULK) material, at least one second ILD layer including a silicon dioxide (SiO₂) based dielectric material, the at least one second ILD layer positioned above the at least one first ILD layer, and a transitional ILD layer including an intermediate dielectric constant material, the transitional ILD layer, excepting any isolation layer, positioned directly below a lowermost one of the at least one second ILD layer; and a plurality of electrically conductive interconnections between the substrate and the integrated circuit chip.

The illustrative aspects of the present invention are designed to solve the problems herein described and other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a conventional chip package.

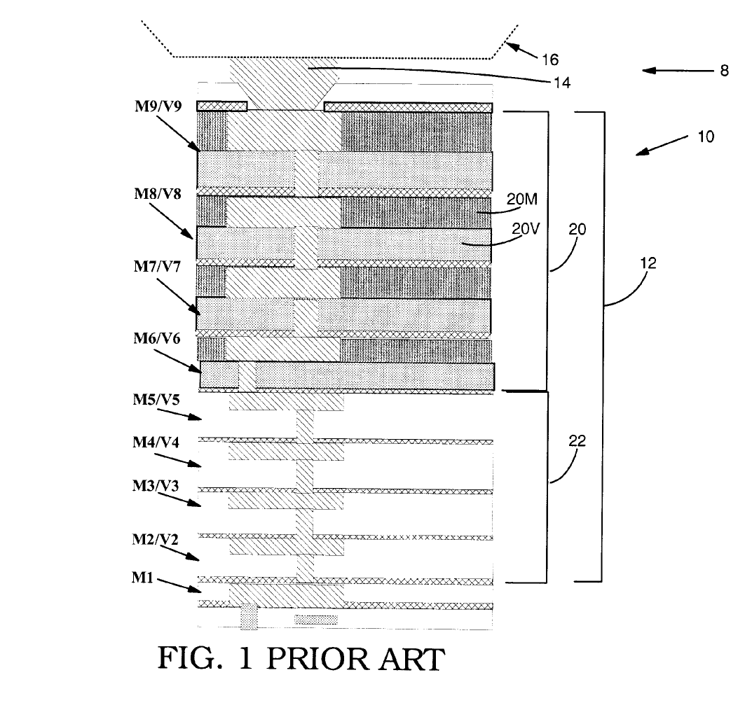

FIG. 2 shows one embodiment of an integrated circuit chip and chip package according to the invention.

FIG. 3 shows an alternative embodiment of an integrated circuit chip and chip package according to the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

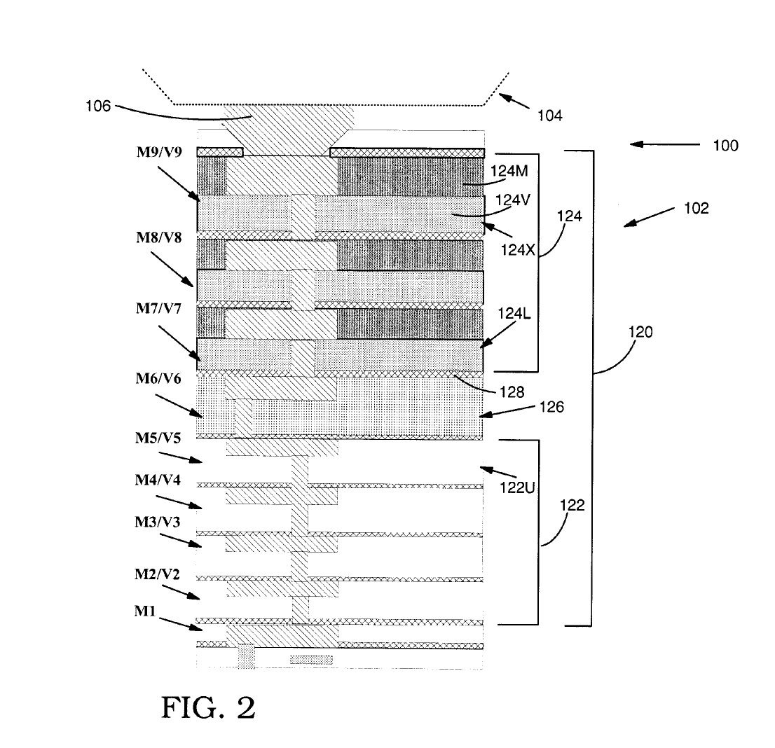

Referring to FIG. 2, one embodiment of an integrated circuit (IC) chip package 100 including an integrated circuit (IC) chip 102 is illustrated. IC chip package 100 also includes a substrate 104 and interconnections 106 (one shown). Substrate 104 may include any now known or later developed circuit board substrate material, such as those including an organic laminate. Substrate 104 may have a coefficient of thermal expansion (CTE) of approximately 6 parts per million per degree Celsius (ppm/° C.), and typically 15-18 ppm/° C. IC chip 102 may have a CTE of approximately 3 ppm/° C. Interconnections 106 may include any now known or later developed electrically conductive interconnections or wire bond connections, e.g., ball grid arrays, etc., between substrate 104 and IC chip 102.

IC chip 102 includes a multi-level interconnect structure 120 according to one embodiment of the invention. Multi-level interconnect structure 120 includes at least one first interlevel dielectric (ILD) layer 122 (four shown) including an ultra low dielectric constant (ULK) material. Each first ILD layer 122 may also include a metal level M2-M5 and a via level V2-V5. “ULK material” is any material having a dielectric constant (k) of less than approximately 2.8, and having a relatively weak mechanical strength relative to a low dielectric constant silicon dioxide (SiO₂) dielectric material of a second ILD layer(s) 124 and an intermediate dielectric constant material of a transitional ILD layer 126, each of which will be described below. For example, ULK material may have an elastic modulus of approximately 6 GPa. Each first ILD layer 122 material may be chosen to meet electrical requirements, lithographic requirements and/or material preferences. In one embodiment, first ILD layer(s) 122, other than an uppermost first ILD layer 122U, may include any dielectric material having a dielectric constant less than approximately 2.7. For example, hydrogenated silicon oxycarbide (SiCOH) generation III, porous SiCOH or other ULK material may be used. SiCOH generation III indicates a version of SiCOH exhibiting a dielectric constant of approximately 2.7, in contrast to earlier generations of SiCOH, which had higher dielectric constant values. The ULK material of uppermost first ILD layer 122U may include any dielectric material having a dielectric constant less than approximately 2.8. For example, a porous SiCOH or SiCOH generation III may be used. In one example, each 1x ILD layer 122, e.g., M2/V2-M4/V4, includes SiCOH generation III and each 2x ILD layer 122, e.g., M5/V5, includes porous SiCOH. However, other configurations are possible.

Multi-level interconnect structure 120 also includes at least one second ILD layer 124 (three shown) including a silicon dioxide (SiO₂) based dielectric material. As shown in FIG. 2, second ILD layer(s) 124 is positioned above the at least one first ILD layer 122. Each second ILD layer 124 may also include a metal level M7-M9 and a via level V7-V9, and may represent either an 8x or a 10x layer depending on technology. Silicon dioxide (SiO₂) based dielectric material may be any now known or later developed silicon dioxide (SiO₂) containing dielectric material having a dielectric constant of greater than approximately 3.0, and a relatively strong mechanical strength relative to intermediate dielectric constant material of transitional ILD layer 126 and the ULK material of first ILD layer(s) 122. For example, ILD layer(s) 124 may have an elastic modulus of greater than 15 GPa. As also shown in FIG. 2, each second ILD layer 124 may include a hybrid scheme including different types of silicon dioxide (SiO₂) based dielectric materials, if desired. For example, one ILD layer 124X may include silicon dioxide (SiO₂) based dielectric material formed using, for example, tetraethyl orthosilicate, Si(OC₂H₅)₄ (TEOS) for a via level 124V, and fluorinated TEOS (FTEOS) for a metal level 124M.

As shown in FIG. 2, multi-level interconnect structure 120 also includes a transitional ILD layer 126 including an intermediate dielectric constant material. Transitional ILD layer 126, excepting any isolation layer(s) 128, is positioned directly below a lowermost one of second ILD layer(s) 124L. The layer directly below a lowermost second ILD layer 124L has been discovered to represent the layer most susceptible to failure. That is, transitional ILD layer 126 (typically a 4x layer including ULK material that is adjacent to silicon dioxide (SiO₂) based dielectric material of second ILD layer(s) 124) has been discovered to receive the highest degree of stress (primarily shear stress). In contrast to conventional ULK material used at this level, “intermediate dielectric constant material” is any material having a dielectric constant that is greater than ULK material of first ILD layers 122 and less than silicon dioxide (SiO₂) based dielectric material of second ILD layers 124, and has a relative mechanical strength greater than ULK material of first ILD layer(s) 122, but less than silicon dioxide (SiO₂) based dielectric material of second ILD layer(s) 124. For example, in one embodiment, intermediate dielectric constant material may have a dielectric constant of greater than approximately 2.8 and less than or equal to approximately 3.0, and an elastic modulus of approximately 7-15 GPa. That is, the intermediate dielectric constant material has a dielectric constant and an elastic modulus greater than that of the ULK material of first ILD layer(s) 122 and less than that of the silicon dioxide (SiO₂) based dielectric material of second ILD layer(s) 124. As a result, intermediate dielectric constant material of transitional ILD layer 126 provides adequate electrical properties, but also absorbs more of the stress than the typical ULK material, which reduces the likelihood of failure. In other words, transitional ILD layer 126 mitigates transmission of stresses created during formation, use and other processes such as wire bond connection processes. In one embodiment, intermediate dielectric constant material of transitional ILD layer 126 may include hydrogenated silicon oxycarbide (SiCOH) generation III (k=approximately 3.0), or SiCOH (k=approximately 2.8-2.9). Note, the latter material is only used where ULK material of first ILD layers 122, including uppermost layer 122U, each have a lower dielectric constant.

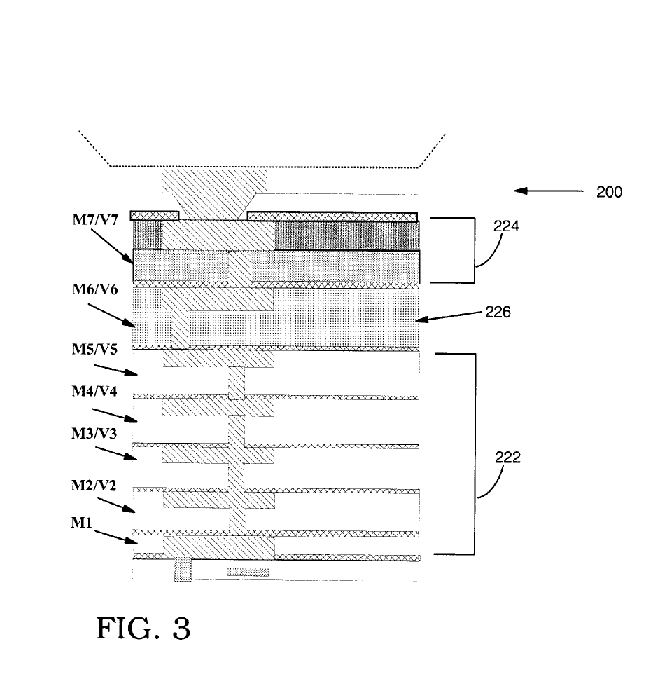

Turning to FIG. 3, an alternative embodiment of an IC chip package 200 is shown. IC chip package 200 is substantially similar to that shown in FIG. 2, except that in this embodiment, fewer ILD layers and only one second ILD layer 224 including a silicon dioxide (SiO₂) based dielectric material is provided. In this embodiment, use of transitional ILD layer 226 allows use of ULK material of first ILD layer(s) 222 in higher levels.

In one embodiment of the invention, a method of forming a multi-level interconnect structure of an IC chip is provided. The method may be implemented using any now known or later developed fabrication processes. Based on FIG. 2 references, in a first step, at least one first ILD layer 122 including a ULK material is formed. In a subsequent step, at least one second ILD layer 124 including a silicon dioxide (SiO₂) based dielectric material is formed, where second ILD layer(s) 124 is positioned above first ILD layer(s) 122. Immediately prior to a lowermost second ILD layer 124L (FIG. 2), excepting any isolation layer 128, transitional ILD layer 126 is formed. As described above, transitional ILD layer 126 includes an intermediate dielectric constant material.

It should be recognized that the number of ILD layers shown is only illustrative and that the number may be changed within the scope of the invention. In addition, the terms “lowermost” and “uppermost” are meant only to provide reference for the embodiments as shown only, and are not meant to limit the invention to any particular special positioning.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of forming a multi-level interconnect structure of an integrated circuit chip, the method comprising the steps of:
forming at least one first interlevel dielectric (ILD) layer including an ultra low dielectric constant (ULK) material;
forming at least one second ILD layer including a silicon dioxide (SiO₂) based dielectric material, the at least one second ILD layer positioned above the at least one first ILD layer; and
forming, immediately prior to a lowermost one of the at least one second ILD layer, excepting any isolation layer, a transitional ILD layer including an intermediate dielectric constant material.

2. The method of claim 1, wherein the at least one first ILD layer other than an uppermost first ILD layer has a dielectric constant less than approximately 2.7.

3. The method of claim 1, wherein the ULK material of an uppermost first ILD layer has a dielectric constant of less than approximately 2.8.

4. The method of claim 1, wherein the intermediate dielectric constant material has a dielectric constant of greater than approximately 2.8 and less than or equal to approximately 3.0.

5. The method of claim 1, wherein the intermediate dielectric constant material has a dielectric constant greater than that of the ULK material and less than that of the silicon dioxide (SiO₂) based dielectric material.

6. The method of claim 1, wherein the intermediate dielectric constant material has an elastic modulus greater than that of the ULK material and less than that of the silicon dioxide (SiO₂) based dielectric material.

7. An integrated circuit chip comprising:
at least one first interlevel dielectric (ILD) layer including an ultra low dielectric constant (ULK) material;
at least one second ILD layer including a silicon dioxide (SiO₂) based dielectric material, the at least one second ILD layer positioned above the at least one first ILD layer; and
a transitional ILD layer including an intermediate dielectric constant material, the transitional ILD layer, excepting any isolation layer, positioned directly below a lowermost one of the at least one second ILD layer.

8. The integrated circuit chip of claim 7, wherein the at least one first ILD layer other than an uppermost first ILD layer has a dielectric constant of less than approximately 2.7.

9. The integrated circuit chip of claim 7, wherein the ULK material of an uppermost first ILD layer has a dielectric constant of less than approximately 2.8.

10. The integrated circuit chip of claim 7, wherein the intermediate dielectric constant material has a dielectric constant of greater than approximately 2.8 and less than or equal to approximately 3.0.

11. The integrated circuit chip of claim 7, wherein the at least one second ILD layer includes only one second ILD layer.

12. The integrated circuit chip of claim 7, wherein the intermediate dielectric constant material has a dielectric constant greater than that of the ULK material and less than that of the silicon dioxide (SiO₂) based dielectric material.

13. The integrated circuit chip of claim 7, wherein the intermediate dielectric constant material has an elastic modulus greater than that of the ULK material and less than that of the silicon dioxide (SiO₂) based dielectric material.

14. An integrated circuit chip package comprising:
a substrate;
an integrated circuit (IC) chip including a multi-level interconnect structure including:
at least one first interlevel dielectric (ILD) layer including an ultra low dielectric constant (ULK) material,
at least one second ILD layer including a silicon dioxide (SiO₂) based dielectric material, the at least one second ILD layer positioned above the at least one first ILD layer, and
a transitional ILD layer including an intermediate dielectric constant material, the transitional ILD layer, excepting any isolation layer, positioned directly below a lowermost one of the at least one second ILD layer; and
a plurality of electrically conductive interconnections between the substrate and the integrated circuit chip.

15. The integrated circuit chip package of claim 14, wherein the at least one first ILD layer other than an uppermost first ILD layer has a dielectric constant of less than approximately 2.7.

16. The integrated circuit chip package of claim 14, wherein the ULK material of an uppermost first ILD layer has a dielectric constant of less than approximately 2.8.

17. The integrated circuit chip package of claim 14, wherein the intermediate dielectric constant material has a dielectric constant of greater than approximately 2.8 and less than or equal to approximately 3.0.

18. The integrated circuit chip package of claim 14, wherein the at least one second ILD layer includes only one second ILD layer.

19. The integrated circuit chip package of claim 14, wherein the substrate has a coefficient of thermal expansion (CTE) of approximately 6 parts per million per degree Celsius (ppm/° C.), and the IC chip has a CTE of approximately 3 ppm/° C.

20. The integrated circuit chip package of claim 14, wherein the intermediate dielectric constant material has a dielectric constant greater than that of the ULK material and less than that of the silicon dioxide (SiO₂) based dielectric material.
